(19) United States
(12) Patent Application Publication
(10) Pub. No.: US 2022/0177296 A1
(43) Pub. Date: Jun. 9, 2022

(54) EPITAXIAL-SILICON WAFER WITH A BURIED OXIDE LAYER

(71) Applicant: Hewlett-Packard Development Company, L.P., Spring, TX (US)

(72) Inventors: Stanley J. Wang, Corvallis, OR (US); James E. Ellenson, Corvallis, OR (US)

(73) Assignee: Hewlett-Packard Development Company, L.P., Spring, TX (US)

(21) Appl. No.: 17/417,834

(22) PCT Filed: Aug. 23, 2019
(86) PCT No.: PCT/US2019/047926

§ 371 Date: Jun. 24, 2021

(51) Int. Cl. B81B 7/00; B81C 1/00

(52) U.S. Cl. CPC B81B 7/008; B81B 2201/051; B81B 2201/052; B81C 1/00238

(57) ABSTRACT

Examples of an epitaxial-silicon wafer with a buried oxide layer are described herein. Examples of methods to manufacture an epitaxial-silicon wafer with a buried oxide layer are also described herein. In some examples, material may be removed from an epitaxial-silicon wafer at a surface opposite an epitaxial surface layer until the epitaxial-silicon wafer is a specified thickness. The thinned epitaxial-silicon wafer may be bonded to an oxidized-silicon wafer at an oxidized surface forming a buried oxide layer.

### BACKGROUND

Semiconductor devices are used to perform a variety of tasks, including electronic, computing and mechanical applications. In some examples, semiconductor devices may be used for micro-fluidic applications. Semiconductor devices may include a number of discrete circuits and/or mechanical devices. These components may be fabricated on a single semiconductor wafer.

### BRIEF DESCRIPTION OF THE DRAWINGS

Various examples will be described below by referring to the following figures.

FIG. 1 is a block diagram illustrating an example of a semiconductor device that includes an epitaxial-silicon wafer with a buried oxide layer;

FIG. 2 is an example flow diagram illustrating a method for manufacturing a semiconductor device with an epitaxial-silicon wafer and a buried oxide layer;

FIG. 3 is an example flow diagram illustrating another method for manufacturing a semiconductor device with an epitaxial-silicon wafer and a buried oxide layer;

FIGS. 4A-4C illustrate examples of various stages for manufacturing a semiconductor device with an epitaxial-silicon wafer and a buried oxide layer; and

FIG. 5 is another example block diagram of a semiconductor device that includes an epitaxial-silicon wafer with a buried oxide layer.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations in accordance with the description; however, the description is not limited to the examples and/or implementations provided in the drawings.

### DETAILED DESCRIPTION

Examples of a semiconductor device having an epitaxial-silicon wafer with a buried oxide (BOX) layer are described herein. Additionally, examples of manufacturing methods of an epi-silicon substrate with a BOX layer for producing micro fluidic micro-electro-mechanical systems (MEMS) devices are described herein.

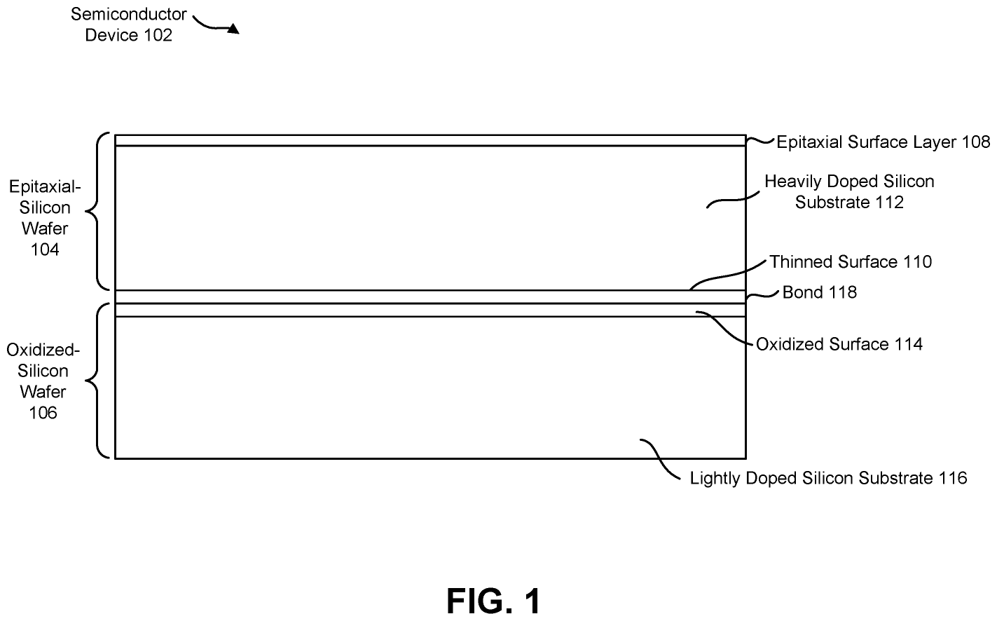

FIG. 1 is a block diagram illustrating an example of a semiconductor device 102 that includes an epitaxial-silicon wafer 104 with a buried oxide layer. The semiconductor device 102 may include an epitaxial-silicon wafer 104 and an oxidized silicon wafer 106.

An epitaxial-silicon wafer 104 may be used for fabrication of electronic circuits and/or micro-machined electro-mechanical structures. For example, a number of electronic circuits and micro-fluidic micro-electro-mechanical systems (MEMS) devices may be fabricated on the epitaxial-silicon wafer 104. The micro-fluidic MEMS devices may be used in conjunction with the electronic circuits to perform fluid transfer operations. Examples of a semiconductor device 102 with electronic circuits and/or micro-fluidic MEMS devices include printheads.

In other examples, the semiconductor device 102 may be used by a fluid ejection device. For example, the semiconductor device 102 may be used in life-science applications (e.g., lab-on-chip fluidic designs), bio-printing, printed manufacturing features and sensors for additive manufacturing applications. These applications may use a fluid other than ink.

This semiconductor device 102 described herein involves a low cost method of achieving a functional fluidic pump based on advanced circuit technologies and MEMS thermal modulation. For example, the semiconductor device 102 may include a buried fluidic feed channel that enables controlled fluid ejection and/or pumping where lower temperatures may ensure the integrity of the fluid involved. For instance, a biosystem fluid (e.g., DNA in a carrier fluid) may not be able to tolerate too much heat.

In some examples, the epitaxial-silicon wafer 104 may be a heavily doped (P+ type) silicon wafer. For proper function of components on the epitaxial-silicon wafer 104 (e.g., electronic circuits, micro-fluidic MEMS devices), the epitaxial-silicon wafer 104 may include an epitaxial surface layer 108. The epitaxial surface layer 108 may be a lightly doped (P− type) epitaxial silicon surface layer of the epitaxial-silicon wafer 104. The epitaxial surface may be formed by epitaxial growth or epitaxial deposition.

In some examples, the semiconductor device 102 may include a buried oxide layer. The buried oxide layer may act as an insulator to improve performance of the electronic circuits and/or micro-fluidic MEMS devices of the epitaxial-silicon wafer 104. For example, the buried oxide layer may reduce parasitic electrical losses. The buried oxide layer may also act as an etch stop for etching performed on the epitaxial-silicon wafer 104.

In some approaches, lead times and costs are unfavorable for a MEMS device manufacturing environment. Additionally, with these approaches, there is no variation in depths for placement of the buried oxide layer. For example, in these approaches the depth of the buried oxide layer is determined by the thickness of epitaxial silicon wafer. However, performance characteristics of the electronic circuitry and the micro-fluidic MEMS device may depend on certain depths of the buried oxide layer.

The present disclosure describes a cost-effective semiconductor device 102 for micro-fluidic MEMS applications. The present disclosure also describes manufacturing processes and methods for producing a semiconductor device 102 having a buried oxide layer at certain depth.

In some examples, the semiconductor device 102 may include a wafer stack. The semiconductor device 102 may include an epitaxial-silicon wafer 104 and an oxidized-silicon wafer 106. The epitaxial-silicon wafer 104 may include a heavily doped (e.g., P+ type) silicon substrate 112. In an example, the heavily doped silicon substrate 112 may be 1 e-2 ohm-cm silicon. One surface of the epitaxial-silicon wafer 104 may be a lightly doped (e.g., P− type) epitaxial surface layer 108. In an example, the epitaxial surface layer 108 may be 10 ohm-cm epitaxial silicon.

The oxidized-silicon wafer 106 may include a lightly doped (e.g., P− type) silicon substrate 116. One surface 114 of the oxidized-silicon wafer 106 may be oxidized. The oxidized surface 114 may also be referred to as an oxide surface. In an example, the lightly doped silicon substrate 116 may be 10 ohm-cm silicon.

Examples of manufacturing methods for the semiconductor device 102 are also described herein. The epitaxial-silicon wafer 104 and the oxidized-silicon wafer 106 may be fabricated separately. For example, the epitaxial-silicon wafer 104 may be fabricated with electronic circuits and/or a micro-fluidic MEMS device. The oxidized-silicon wafer 106 may be fabricated as a separate component.

Material may be removed from the epitaxial-silicon wafer 104 at the surface 110 opposite the epitaxial surface layer 108. The surface from which material is removed may be referred to as the thinned surface 110. The material may be removed from the epitaxial-silicon wafer 104 until the epitaxial-silicon wafer is a specified thickness (e.g., 50, 75 or 100 micrometers (um)). The specified thickness of the epitaxial-silicon wafer 104 may be determined based on performance characteristics of the electronic circuitry and the micro-fluidic MEMS device. In some examples, the electronic circuitry and the micro-fluidic MEMS device are fabricated on the epitaxial-silicon wafer 104 before removing the material from the epitaxial-silicon wafer 104 and bonding the thinned epitaxial-silicon wafer 104 to the oxidized-silicon wafer 106.

In an example, removing the material from the epitaxial-silicon wafer 104 may include grinding the surface 110 opposite the epitaxial surface layer 108 until the epitaxial-silicon wafer 104 is the specified thickness. Other processes to remove material from the thinned surface 110 may include polishing, etching, other subtractive manufacturing process or a combination thereof.

In another example, the epitaxial-silicon wafer 104 may be attached to a temporary handle wafer to aid in removing the material from the epitaxial-silicon wafer 104. For instance, the handle wafer may be attached to the epitaxial surface layer 108. A subtractive manufacturing process (e.g., grinding, polishing, etc.) may be performed on the thinned surface 110 to remove material from the epitaxial-silicon wafer 104 until the epitaxial-silicon wafer 104 is a specified thickness. The handle wafer may then be removed from the epitaxial-silicon wafer 104.

The thinned epitaxial-silicon wafer 104 may be bonded to the oxidized-silicon wafer 106 at the oxidized surface 114. In an example, the bond 118 between the thinned epitaxial-silicon wafer 104 and the oxidized-silicon wafer 106 may be a low-temperature bond. For example, the low-temperature bond may be an adhesive bond. It should be noted that the low-temperature may protect the electronic circuitry and the micro-fluidic MEMS device of the epitaxial-silicon wafer 104 from heat-related damage. For example, if high-temperature bonding techniques (e.g., plasma bonding, annealing) were used to bond the epitaxial-silicon wafer 104 and the oxidized-silicon wafer 106, then the pre-fabricated electronic circuitry and/or micro-fluidic MEMS devices may be damaged.

It should be noted that upon bonding the thinned epitaxial-silicon wafer 104 to the oxidized-silicon wafer 106, the oxidized surface 114 of the oxidized-silicon wafer 106 forms a buried oxide layer for the semiconductor device 102. Because the epitaxial-silicon wafer 104 is thinned down to the specified thickness, the oxidized surface 114 (i.e., the buried oxide layer) is located at a depth that optimizes the performance of the electronic circuitry and/or micro-fluidic MEMS devices of the semiconductor device 102.

The described methods for manufacturing the semiconductor device 102 are flexible for supporting placement of the buried oxide layer at different depths depending on the thickness of the thinned epitaxial-silicon wafer 104. Furthermore, the manufacturing method is fast, and provides for a long-term supply of buried-oxide silicon wafers with a compatible epitaxial surface layer 108.

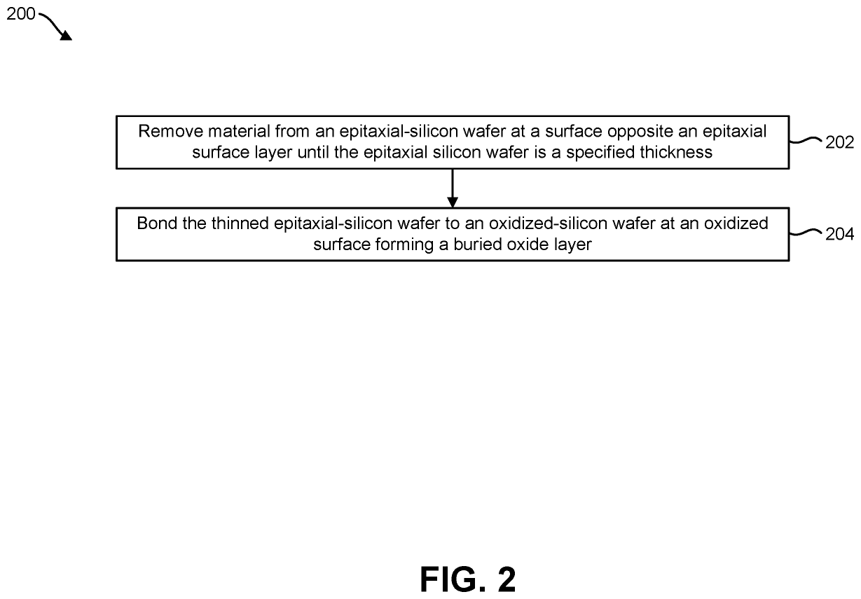

FIG. 2 is an example flow diagram illustrating a method 200 for manufacturing a semiconductor device 102 with an epitaxial-silicon wafer 104 and a buried oxide layer. The semiconductor device 102 may include the epitaxial-silicon wafer 104 and an oxidized-silicon wafer 106. The epitaxial-silicon wafer 104 may include a heavily doped silicon substrate 112 and a lightly doped epitaxial surface layer 108. The oxidized-silicon wafer 106 may include a lightly doped silicon substrate 116 with an oxidized surface 114.

Material may be removed 202 from the epitaxial-silicon wafer 104 at a surface 110 opposite the epitaxial surface layer 108 until the epitaxial-silicon wafer 104 is a specified thickness. For example, removing 202 the material from the epitaxial-silicon wafer 104 may include grinding the surface 110 opposite the epitaxial surface layer 108 until the epitaxial-silicon wafer 104 is the specified thickness. In other examples, removing 202 the material from the epitaxial-silicon wafer 104 may include polishing, etching, or other subtractive manufacturing process.

The thinned epitaxial-silicon wafer 104 may be bonded 204 to the oxidized-silicon wafer 106 at the oxidized surface 114 forming a buried oxide layer. In an example, bonding 204 the thinned epitaxial-silicon wafer 104 to the oxidized-silicon wafer 106 may include a low-temperature bond 118. For instance, the low-temperature bond 118 may include an adhesive bond. It should be noted that upon bonding the epitaxial-silicon wafer 104 to the oxidized-silicon wafer 106, the oxidized surface 114 is the buried oxide layer for the epitaxial-silicon wafer 104.

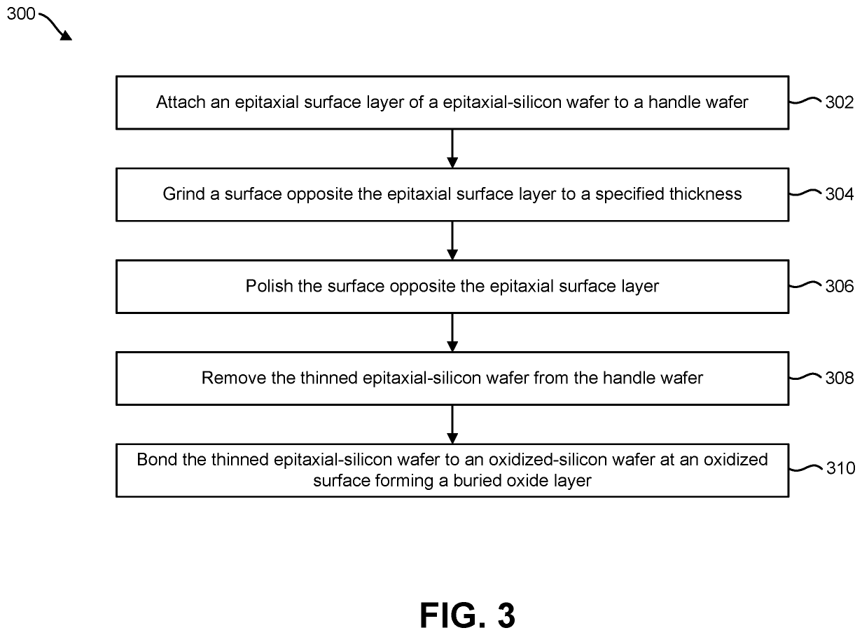

FIG. 3 is an example flow diagram illustrating another method 300 for manufacturing a semiconductor device 102 with an epitaxial-silicon wafer 104 and a buried oxide layer. The epitaxial-silicon wafer 104 may include a heavily doped silicon substrate 112 and a lightly doped epitaxial surface layer 108. In an example, the epitaxial-silicon wafer 104 may include electronic circuitry and a micro-fluidic micro-electro-mechanical systems (MEMS) device.

An epitaxial surface layer 108 of the epitaxial-silicon wafer 104 may be attached 302 to a handle wafer. For example, the epitaxial-silicon wafer 104 may be attached 302 to the handle wafer with a low-temperature bond 118 (e.g., adhesive bond).

A surface 110 opposite the epitaxial surface layer 108 may be ground 304 until the epitaxial-silicon wafer 104 is a specified thickness. For example, an abrasive grinding wheel or other abrasive cutting tool may be applied to the surface 110 opposite the epitaxial surface layer 108. Material may be removed from the surface 110 until the epitaxial surface layer 108 is a specified thickness.

The surface 110 opposite the epitaxial surface layer 108 may be polished 306. For example, abrasive or chemical polishing slurry may be applied to the thinned surface 110. A polishing device may be applied to the thinned surface 110 to smooth the thinned surface 110.

The thinned epitaxial-silicon wafer 104 may be removed 308 from the handle wafer. For example, a mechanical process (e.g., cutting, grinding shearing, etc.) or a chemical process (e.g., adhesive solvent) may be applied to separate the thinned epitaxial-silicon wafer 104 from the handle wafer.

The thinned epitaxial-silicon wafer 104 may be bonded 310 to an oxidized-silicon wafer 106 at an oxidized surface 114 forming a buried oxide layer. For example, the oxidized-silicon wafer 106 may include a lightly doped silicon substrate 116 with an oxidized surface 114. In an example, bonding 310 the thinned epitaxial-silicon wafer 104 to the oxidized-silicon wafer 106 may include a low-temperature bond 118. For instance, the low-temperature bond 118 may include an adhesive bond between the thinned surface 110 of the epitaxial-silicon wafer 104 and the oxidized surface 114 of the oxidized-silicon wafer 106.

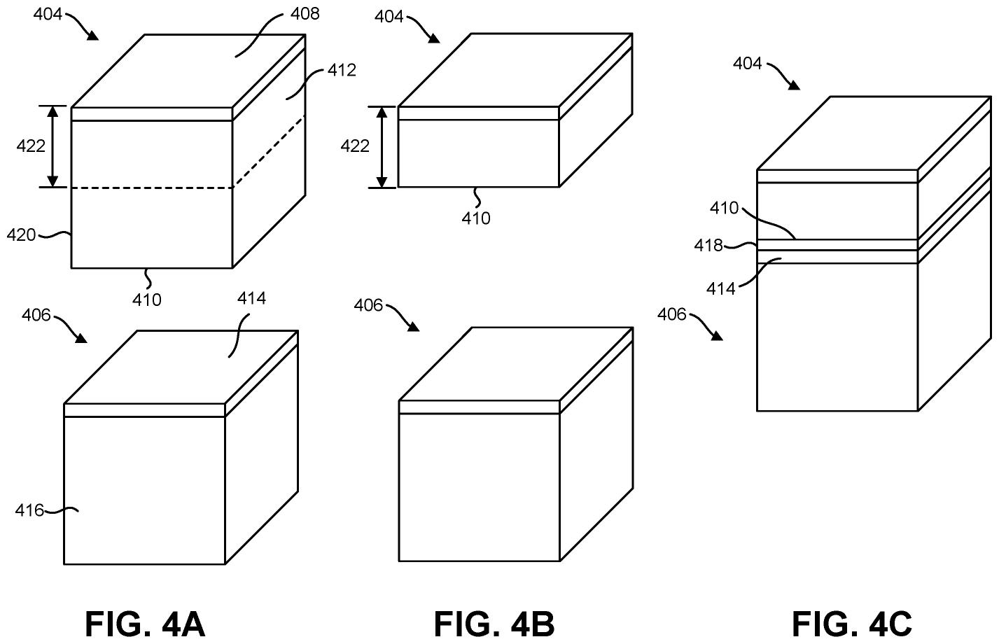

FIGS. 4A-4C illustrate examples of various stages for manufacturing a semiconductor device 102 with an epitaxial-silicon wafer 404 and a buried oxide layer. FIG. 4A illustrates an example of an epitaxial-silicon wafer 404 and an oxidized-silicon wafer 406. The epitaxial-silicon wafer 404 includes a heavily doped silicon substrate 412 and a lightly doped epitaxial surface layer 408. The epitaxial-silicon wafer 404 may be fabricated with a thickness that is greater than a final specified thickness 422. Therefore, material 420 (indicated in FIG. 4A as below the dashed line) is to be removed from the epitaxial-silicon wafer 404. The material 420 is to be removed from the epitaxial-silicon wafer 404 at a surface 410 that is opposite the epitaxial surface layer 408.

In FIG. 4A, the oxidized-silicon wafer 406 includes a lightly doped silicon substrate 416 with an oxidized surface 414. It should be noted that at this stage, the epitaxial-silicon wafer 404 and the oxidized-silicon wafer 406 are separate.

In FIG. 4B, the thinned epitaxial-silicon wafer 404 is shown after the material 420 is removed from the surface 410 opposite the epitaxial surface layer 408 until the epitaxial-silicon wafer 404 is the specified thickness 422. For example, the material 420 may be removed from the thinned surface 410 using grinding or another subtractive manufacturing process. It should be noted that at this stage, the epitaxial-silicon wafer 404 and the oxidized-silicon wafer 406 are still separate. In other words, the material 420 is removed from the epitaxial-silicon wafer 404 while the epitaxial-silicon wafer 404 is separate from the oxidized-silicon wafer 406.

In FIG. 4C, the oxidized-silicon wafer 406 is bonded to the thinned epitaxial-silicon wafer 404 at the oxidized surface 414. For example, the bond 418 between the thinned epitaxial-silicon wafer 404 and the oxidized-silicon wafer 406 may be a low-temperature bond (e.g., adhesive bond). The bond 418 may be located between the thinned surface 410 and the oxidized surface 414. Upon bonding the epitaxial-silicon wafer 404 to the oxidized-silicon wafer 406, the oxidized surface 414 is the buried oxide layer for the epitaxial-silicon wafer 404.

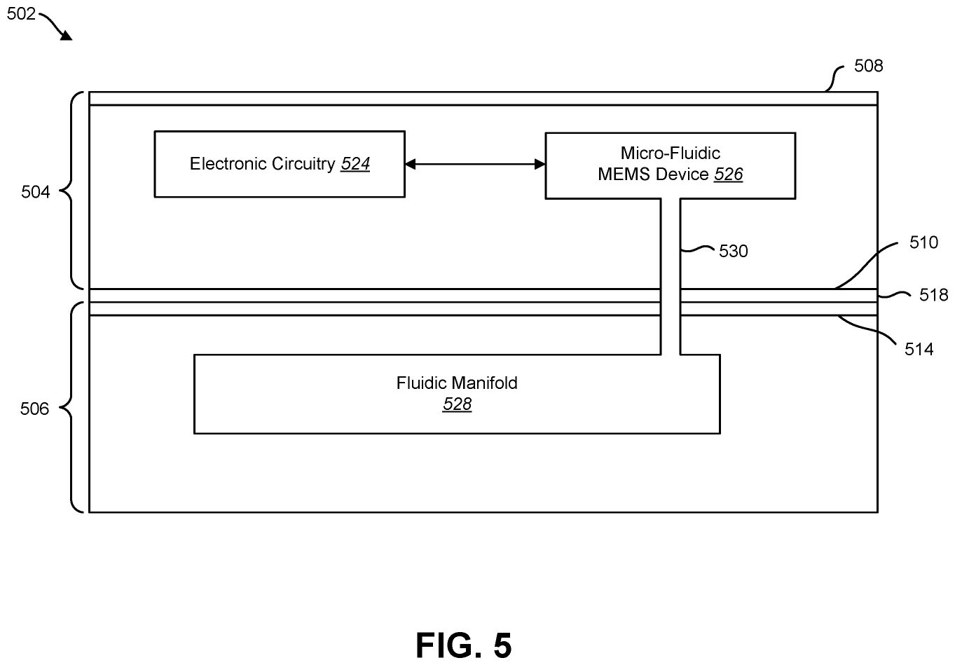

FIG. 5 is another example block diagram of a semiconductor device 502 that includes an epitaxial-silicon wafer 504 with a buried oxide layer. The semiconductor device 502 includes an epitaxial-silicon wafer 504 and an oxidized-silicon wafer 506.

The semiconductor device 502 may be fabricated as described in connection with FIG. 1. For example, the epitaxial-silicon wafer 504 includes an epitaxial surface layer 508. Material is removed from the epitaxial-silicon wafer 504 at a surface 510 opposite the epitaxial surface layer 508 until the epitaxial-silicon wafer 504 is a specified thickness. The oxidized-silicon wafer 506 may be bonded to the thinned epitaxial-silicon wafer 504 at an oxidized surface 514 forming a buried oxide layer.

In this example, the epitaxial-silicon wafer 504 includes electronic circuitry 524 and a micro-fluidic micro-electro-mechanical systems (MEMS) device 526. The electronic circuitry 524 may be in communication with the micro-fluidic MEMS device 526. For example, the electronic circuitry 524 may provide a signal (e.g., electrical current and/or voltage) to the micro-fluidic MEMS device 526.

The micro-fluidic MEMS device 526 may perform an operation on a fluid. For example, the micro-fluidic MEMS device 526 may cause movement of a fluid from one location to another within the semiconductor device 502. In another example, the micro-fluidic MEMS device 526 may emit a fluid from the semiconductor device 502 based on signals from the electronic circuitry 524.

The electronic circuitry 524 may be adjacent to the micro-fluidic MEMS device 526 on a same layer of the semiconductor device 502. For example, the electronic circuitry 524 and the micro-fluidic MEMS device 526 may be located at the epitaxial-silicon wafer 504. Therefore, the electronic circuitry 524 and the micro-fluidic MEMS device 526 are located within the same vertical layer of the semiconductor stack.

In an example, the electronic circuitry 524 and the micro-fluidic MEMS device 526 may be fabricated on the epitaxial-silicon wafer 504 before bonding with the oxidized-silicon wafer 506. To prevent damage to the electronic circuitry 524 and the micro-fluidic MEMS device 526, the bond 518 may be a low-temperature bond (e.g., adhesive bond).

In some examples, the structure of the micro-fluidic MEMS device 526 may be adjusted during the material removal process on the epitaxial-silicon wafer 504. For example, intake ports for the micro-fluidic MEMS device 526 may be exposed during grinding on the thinned surface 510 of the epitaxial-silicon wafer 504.

The oxidized-silicon wafer 506 may include a fluidic manifold 528 to provide a fluid to the micro-fluidic MEMS device 526 of the epitaxial-silicon wafer 504. For example, the fluidic manifold 528 may be a cavity within the oxidized-silicon wafer 506. In some examples, the fluidic manifold 528 may include an intake port to receive a fluid and/or an exit port to discharge the fluid. A fluid interface 530 may connect the fluidic manifold 528 to the micro-fluidic MEMS device 526. The fluid interface 530 may span across the oxidized-silicon wafer 506 to the micro-fluidic MEMS device 526. Fluid may pass from the fluidic manifold 528 to the micro-fluidic MEMS device 526 through the fluid interface 530.

1. A method, comprising:
removing material from an epitaxial-silicon wafer at a surface opposite an epitaxial surface layer until the epitaxial-silicon wafer is a specified thickness; and
bonding the thinned epitaxial-silicon wafer to an oxidized-silicon wafer at an oxidized surface forming a buried oxide layer.

2. The method of claim 1, wherein removing the material from the epitaxial-silicon wafer comprises grinding the surface opposite the epitaxial surface layer until the epitaxial-silicon wafer is the specified thickness.

3. The method of claim 1, wherein bonding the thinned epitaxial-silicon wafer to the oxidized-silicon wafer comprises a low-temperature bond.

4. The method of claim 3, wherein the low-temperature bond comprises an adhesive bond.

5. The method of claim 1, wherein the epitaxial-silicon wafer comprises a heavily doped silicon substrate and a lightly doped epitaxial surface layer.

6. The method of claim 1, wherein the oxidized-silicon wafer comprises a lightly doped silicon substrate with the oxidized surface.

7. A method, comprising:
attaching an epitaxial surface layer of a epitaxial-silicon wafer to a handle wafer;
grinding a surface opposite the epitaxial surface layer until the epitaxial-silicon wafer is a specified thickness;
polishing the surface opposite the epitaxial surface layer;
removing the thinned epitaxial-silicon wafer from the handle wafer; and
bonding the thinned epitaxial-silicon wafer to an oxidized-silicon wafer at an oxidized surface forming a buried oxide layer.

8. The method of claim 7, wherein the epitaxial-silicon wafer comprises electronic circuitry and a micro-fluidic micro-electro-mechanical systems (MEMS) device.

9. The method of claim 8, wherein the electronic circuitry and the micro-fluidic MEMS device are fabricated on the epitaxial-silicon wafer before removing material from the epitaxial-silicon wafer and bonding the thinned epitaxial-silicon wafer to the oxidized-silicon wafer.

10. The method of claim 8, wherein the specified thickness of the epitaxial-silicon wafer is determined based on performance characteristics of the electronic circuitry and the micro-fluidic MEMS device.

11. The method of claim 8, wherein bonding the thinned epitaxial-silicon wafer to the oxidized-silicon wafer comprises a low-temperature bond that protects the electronic circuitry and the micro-fluidic MEMS device from heat-related damage.

12. A semiconductor device, comprising:
an epitaxial-silicon wafer comprising an epitaxial surface layer, wherein material is removed from the epitaxial-silicon wafer at a surface opposite the epitaxial surface layer until the epitaxial-silicon wafer is a specified thickness; and
an oxidized-silicon wafer bonded to the thinned epitaxial-silicon wafer at an oxidized surface forming a buried oxide layer.

13. The semiconductor device of claim 12, wherein the epitaxial-silicon wafer comprises electronic circuitry and a micro-fluidic micro-electro-mechanical systems (MEMS) device.

14. The semiconductor device of claim 13, wherein the electronic circuitry is adjacent to the micro-fluidic MEMS device on a same layer of the epitaxial-silicon wafer.

15. The semiconductor device of claim 12, wherein the oxidized-silicon wafer comprises a fluidic manifold to provide a fluid to a micro-fluidic MEMS device of the epitaxial-silicon wafer.
